(19) United States
(12) Patent Application Publication
(10) Pub. No.: US 2010/0047955 A1
(43) Pub. Date: Feb. 25, 2010

(54) Interconnection system for photovoltaic modules

(75) Inventor: Aarohi Vijh, Sylvania, OH (US)

Correspondence Address: EMCH, SCHAFFER, SCHAUB & PORCELLO CO, P O BOX 916, ONE SEAGATE SUITE 1980, TOLEDO, OH, 43697, US

(73) Assignee: Xunlight Corporation

(21) Appl. No.: 12/583,284

(22) Filed: Aug. 18, 2009

Related U.S. Application Data
(60) Provisional application No. 61/090,109, filed on Aug. 19, 2008.

(51) Int. Cl. H01L 31/18; H01L 21/50

(52) U.S. Cl. 438/65; 438/66; 257/E21.502; 257/E21.499

(57) ABSTRACT

Methods for forming series-interconnected solar cells that use metal foils as substrates are provided. In an embodiment of the invention, a metallic substrate-type solar cell having the following structure is provided: a metal substrate, a semiconductor, and a transparent conducting front contact. In another embodiment of the invention, optional current collecting grids may be provided. An insulating carrier material layer may be provided bonded to the metal substrate.

This application claims the benefit of provisional patent application Ser. No. 61/090,109, filed Aug. 19, 2008.

### BACKGROUND OF THE INVENTION

This invention relates to the field of photovoltaic modules. In particular, this invention relates to series-interconnection of thin-film solar cells to form a solar module.

### SUMMARY OF THE INVENTION

The invention provides systems and methods for series-interconnection of solar cells for photovoltaic modules. Various aspects of the invention described herein may be applied to any of the particular applications set forth below or for other types of photovoltaic or energy generation systems. The invention may be applied as a standalone system or method, or as part of an application, such as various manufacturing systems. It shall be understood that different aspects of the invention can be appreciated individually, collectively, or in combination with each other. Fabrication of solar cell layers on flexible metal foil, such as stainless-steel foil, has the advantage that a continuous roll-to-roll process may be used for manufacture. The resulting product may be a single long solar cell up to several thousand feet long. However, this long solar material may be cut into smaller units or subcells, and these units may be series connected to form a string with higher voltage output.

The invention provides a method of achieving series connection for solar cells fabricated on metal substrates such as a flexible stainless steel foil. The method of interconnection described herein may not require that the cells be fabricated on an insulating substrate (e.g. polymers). Therefore, conventional processes and equipment for coating solar material onto metal foils can be used for cell fabrication. Fabrication of cells on polymers is sometimes difficult due to outgassing, wrinkling or shrinkage of the polymer film. Further, in the present invention, the steps for interconnection may be performed after the solar cell structure is fully formed. Problems of misalignment of the work-piece may thus be avoided.

The method described herein is distinct from the conventional methods for interconnecting cell fabricated on metal foils, which typically involve first cutting the coated foil into mechanically separate slabs and then connecting the slabs electrically in series. In the present invention, the slabs may be electrically separated but may never be mechanically separated from each other. This may translate to higher product yields since product loss due to handling of individual pieces during series interconnection may be greatly reduced or eliminated.

Another aspect of the invention provides apparatus for interconnection of thin film solar cells that may incorporate the systems and methods described herein. For example, the apparatus may include interconnected thin film solar cells, which may be formed by the steps described herein, and any intermediate articles thereof.

Other goals and advantages of the invention will be further appreciated and understood when considered in conjunction with the following description and accompanying drawings. While the following description may contain specific details describing particular embodiments of the invention, this should not be construed as limitations to the scope of the invention but rather as an exemplification of preferable embodiments. For each aspect of the invention, many variations are possible as suggested herein that are known to those of ordinary skill in the art. A variety of changes and modifications can be made within the scope of the invention without departing from the spirit thereof.

### Incorporation by Reference

All publications, patents, and patent applications mentioned in this specification are herein incorporated by reference to the same extent as if each individual publication, patent, or patent application was specifically and individually indicated to be incorporated by reference.

Other objects and advantages of the present invention will become apparent to those skilled in the art upon a review of the following detailed description of the preferred embodiments and the accompanying drawings.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings of which:

FIGS. 1A-1G illustrates steps for forming a metallic substrate-type solar cell, including application of cell-side mechanical support.

FIGS. 2A-2F illustrates steps for forming a metallic substrate-type solar cell, including application of substrate-side mechanical support.

### DETAILED DESCRIPTION OF THE PREFERRED EMBODIMENT(S)

While preferable embodiments of the invention have been shown and described herein, it will be obvious to those skilled in the art that such embodiments are provided by way of example only. Numerous variations, changes, and substitutions will now occur to those skilled in the art without departing from the invention. It should be understood that various alternatives to the embodiments of the invention described herein may be employed in practicing the invention.

Embodiments of the invention advantageously provide for methods for forming solar cell modules (or solar cells) with greater convenience over prior methods.

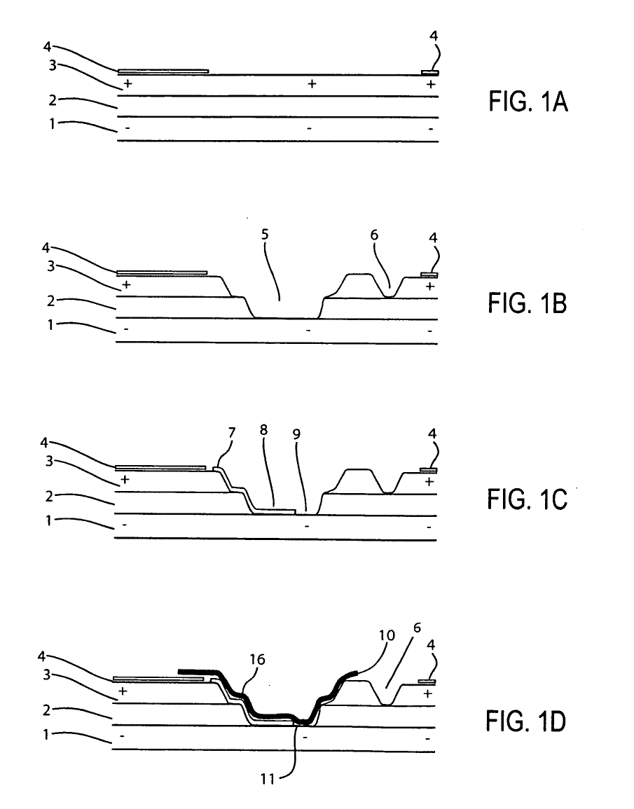

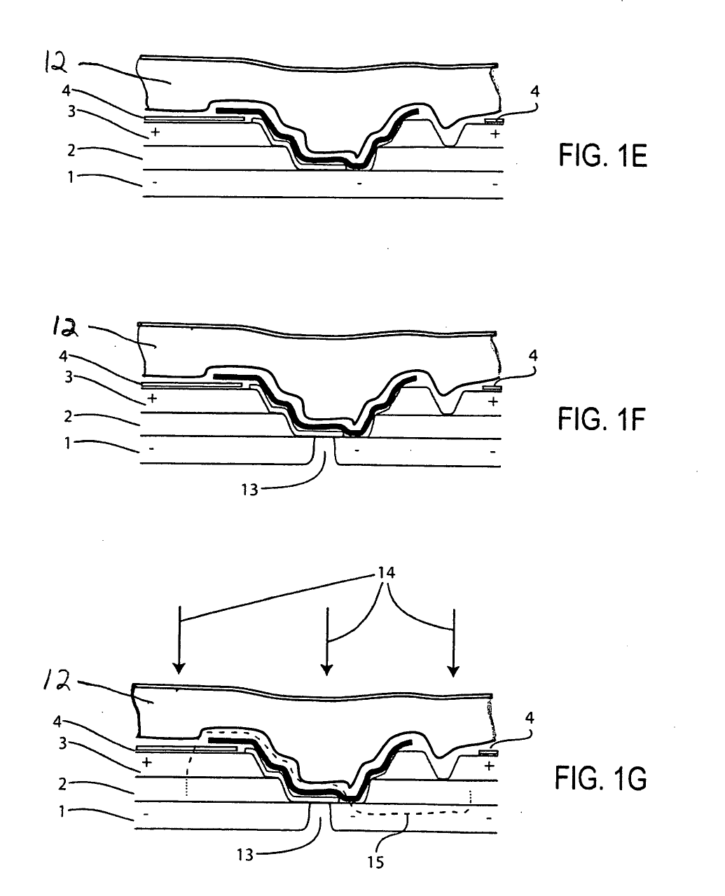

FIG. 1 illustrates a method of interconnecting solar cells including application of cell-side mechanical support in accordance with one aspect of the invention. FIG. 1A shows a first step in accordance with one embodiment of the invention. A metallic substrate-type solar cell having the following structure may be provided: a metal substrate 1, a semiconductor 2, and a transparent conducting front contact 3. The metal substrate 1 may be coated with other conducting layers, but herein any such layers are considered part of the metal substrate 1. A current collection grid 4 may also be required to reduce the series resistance of the solar cell. If required, it may be applied at any point before step 5 (see FIG. 1E). This typical structure is shown in FIG. 1A. The metal substrate 1 could comprise stainless steel, mild steel, coated steel, molybdenum, titanium, or indeed any sufficiently conductive and stable metal foil or sheet. The semiconductor 2 could be amorphous silicon, microcrystalline silicon, nanocrystalline silicon, cadmium telluride, a copper-indium-gallium-selenium-sulfur alloy, cadmium sulfide, sensitized titanium oxide, or indeed any thin-film semiconductor material and structure capable of converting light into electricity. The front contact 3 could comprise zinc oxide, aluminum-zinc-oxide, indium oxide, indium-tin oxide, indium-gallium oxide, cadmium oxide, tin oxide, cadmium stannate, fluorine-doped tin oxide, or any other material capable of sufficient electrical conductivity and light transmission. The current collection grid 4 may comprise metal wire, evaporated metal, silver paste, metallic paste, conductive carbon paste, conductive epoxy, conductive thermoplastic, or combinations thereof, or indeed any sufficiently conductive material or materials with sufficient adhesion to the front contact 3.

The structure shown in FIG. 1A may be implemented by thin-film deposition, such as chemical vapor deposition. Alternatively, any other methods known in the art for creating such a structure, such as physical vapor deposition, plasma enhanced chemical vapor deposition (PECVD), atmospheric pressure chemical vapor deposition (APCVD), reduced pressure chemical vapor deposition (RPCVD), metal organic chemical vapor deposition (MOCVD), anodization, collimated sputtering, spray pyrolysis, ink-jet printing, ionized physical vapor deposition, vacuum evaporation, molecular beam deposition, ion beam deposition, atomic layer deposition, electrodeposition, screen binding, hot-wire processes, sol-gel processes, screen printing, electroplating, etc. may be implemented. Such methods may also be applied to create a structure in the following discussion at any step.

With reference to FIG. 1B, in a second step, laser scribing, mechanical scribing, chemical etching, lithographic etching, electro-discharge machining, or any other scribing, etching, or masking methods may be used to open a connection scribe 5 and an isolation scribe 6. The connection scribe 5 is often referred to in the art, and also hereinafter, as a “via” or a “via scribe”. The via scribe 5 may expose the metal substrate. The via scribe may remove the semiconductor layer and all layers above in selected areas, wherein layers above may include a front contact layer and any other layer that may be on that side of the substrate, regardless of cell orientation. Forming isolation scribe 6 may comprise removing a portion of the transparent conducting front contact layer 3.

With reference to FIG. 1C, in a third step, an insulating barrier material 7 may be applied to the slope of the via scribe 5 on the side away from the isolation scribe 6, and to a portion 8 of the bottom of the via scribe 5. A second portion 9 of the via scribe 5 proximate the isolation scribe 6 may be left exposed. The barrier material could be a thermally cured or light cured material, such as a heat cured polymer, a UV cured polymer, insulating tape, or any other insulating material. Some examples of suitable materials may include polyurethane, epoxy amines, and acrylates. The barrier can be applied by screen printing, by ink-jet printing, by spray coating, by sputtering, by manual application, such as by hand painting using a brush, or by another method, such as those discussed previously.

With reference to FIG. 1D, in a fourth step, a conducting material 16 may be applied over the barrier 7 and may extend to cover the exposed via portion 9 to form an electrical contact 11, and may also extend to cover a portion of the front contact (and optionally, the current collection grid 4) of the cell away from the isolation scribe 6, thus forming a conductive bridge 10. The conductive material could be formed of one or more elemental metals, such as, e.g., copper, gold, silver, platinum or palladium. In some embodiments of the invention, the conductive material could be a conductive ink or conductive adhesive, such as silver ink, copper tape, or another conductive material. In some cases, the conductive material may be applied by methods such as silk screening, ink-jet or other spraying techniques, sputtering, vacuum evaporation, flame spraying of metals, and so forth.

With reference to FIG. 1E, in a fifth step, an insulating, transparent, protective encapsulant 12 may be provided on a front surface of the solar cell. In an embodiment of the invention, the protective encapsulant 12 may be laminated to the front of the solar cell. The protective encapsulant 12 may provide sufficient mechanical support to the solar cells and module. In some implementations, the protective encapsulant 12 can be formed of ethyl-vinyl acetate. Alternatively, other materials, such as silicone, silicone gel, epoxy, polydimethyl siloxane, RTV silicone rubber, polyvinyl butyral, thermoplastic polyurethane, a polycarbonate, an acrylic, a fluoropolymer, a urethaneis, or any material as known in the art may be used as a protective encapsulant.

With reference to FIG. 1F, in a sixth step, laser scribing, mechanical scribing, chemical etching, lithographic etching, electro-discharge machining, or any other scribing, etching, or masking methods may be used to open a substrate isolation scribe 13, thus dividing the solar material into two series interconnected solar cells. Such solar cells may form proximate or neighboring subcells that may still be mechanically connected by the protective encapsulant 12.

With reference to FIG. 1G, in a seventh step, under illumination 14, a photo current 15 may be generated in the two solar cells. The photo current 15 may flow in series between the two cells. The photovoltages of the combination may be the sum of the photovoltages of the two cells.

It will be appreciated that more than two cells can be interconnected in series. The spacing between interconnects can be kept the same, which may allow all of the cells to generate the same amount or quantity of photocurrent. In other implementations, the spacing between interconnects may be varied, and the cells may generate varying amounts of photocurrent.

In some embodiments of the invention, various materials may be included in the metal substrate 1. For example, a metal substrate may be formed of one or more elemental metals or metal alloy, such as stainless steel, aluminum, copper, iron, nickel, silver, zinc, molybdenum, titanium, tungsten, vanadium, rhodium, niobium, chromium, tantalum, platinum, gold, or any alloys, multilayers or combinations thereof, which may include a metal coated with any materials such as silver, aluminum, copper, molybdenum, iron, nickel, titanium, zinc oxide or combinations thereof. The metal substrate may or may not include a back-reflector. In some cases, the metal substrate may have a diffusion barrier layer or anti-corrosion layer.

In some embodiments a semiconductor 2 may include materials such as silicon-based materials such as thin-film silicon, amorphous silicon, or crystalline silicon, copper indium diselenide (CIS), copper indium gallium selenide (CIGS), cadmium telluride (CdTe), gallium indium phosphide (GaInP), gallium arsenide GaAs, and germanium Ge, and any other semiconductor material known in the art, and/or may be formed of an amorphous silicon stack, a copper indium gallium selenide (CIGS)/CdS stack, or a CdTe/CdS stack, or Cu(In, Ga)Se, ZnSe/CIS, ZnO/CIS, or Mo/CIS/CdS/ZnO.

In some embodiments a transparent conducting front contact 3 may include materials such as various transparent conductive oxides (TCOₛ) such as various tin oxides (SiOₓ), SnO₂, fluorine-doped tin oxide (SnO₂:F), indium tin oxide (ITO), zinc-oxide such as zinc oxide doped with aluminum, fluorine, gallium, or boron, indium zinc oxide, cadmium sulfide (CdS), cadmium oxide, or other transparent conducting materials known in the art.

A current collection grid may be provided and may include any material known in the art known to be used for current collection grids. For example, the current collection grid may include conductive epoxy, conductive ink, or a metal such as copper, aluminum, nickel, or silver or alloy thereof, conductive glue, or conductive plastic. Any of the embodiments may be combined to form any combination of materials to provide materials for solar cells.

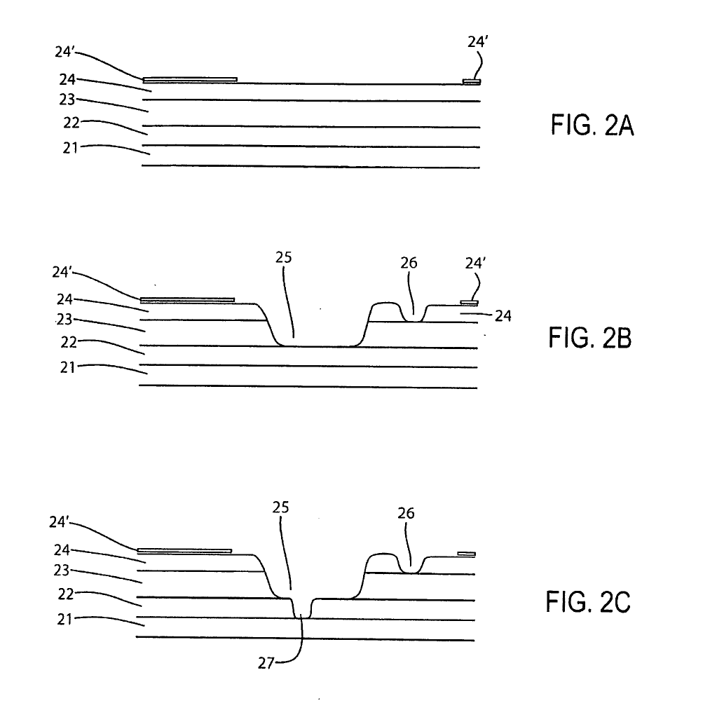

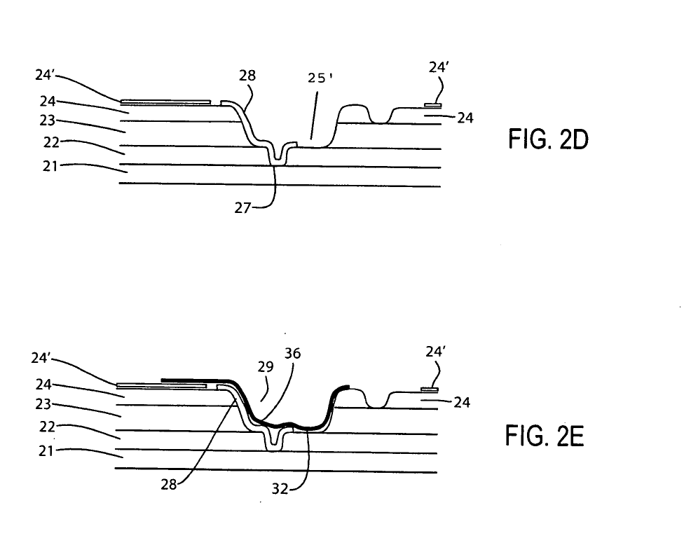

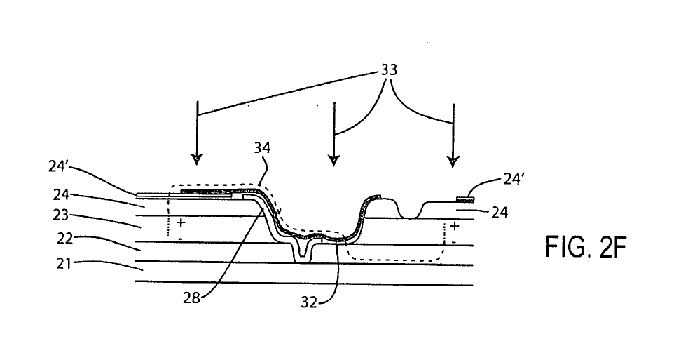

FIG. 2 illustrates a method of interconnecting solar cells including application of substrate-side mechanical support in accordance with another aspect of the invention. With reference to FIG. 2A, in a first step, a metallic substrate-type solar cell is provided, comprising a metal or metallic substrate 22, semiconductor layers 23, front transparent contact 24 and optional current collecting grids 24′. The metal substrate is in contact with (or bonded to) an insulating carrier material layer. The insulating carrier material 21 may provide sufficient mechanical support to the solar cells and module.

In a preferable embodiment of the invention, in a first step, a complete metallic substrate-type solar cell is provided comprising a metal or metallic substrate 22, semiconductor layers 23, front transparent contact 24 and optional current collecting grids 24′. The metal substrate 22 is then bonded to an insulating carrier material layer 21. The insulating carrier material 21 may provide sufficient mechanical support to the solar cells and module. The insulating carrier material 21 may provide sufficient mechanical support to the solar cells and module. The insulating carrier material 21 may provide sufficient mechanical support to the solar cell and module the insulating carrier material 21 may be applied after the complete solar cell structure has been fabricated, in which case the insulating carrier may not be a substrate of the solar cell.

The structure shown in FIG. 2A may be implemented by thin-film deposition. In some cases, the insulating carrier material 21 may be laminated to the back of the solar cell, and may be adjacent to the metal substrate layer. Alternatively, any other methods known in the art for creating such a structure may be implemented.

With reference to FIG. 2B, in a second step, laser scribing, mechanical scribing, chemical etching, lithographic etching, electro-discharge machining, or any other scribing, etching, or masking methods may be used to open a via scribe 25 and an isolation scribe 26. The via scribe 25 may expose the metal substrate 22. The via scribe may remove the semiconductor layer and all layers above in selected areas, wherein layers above may include a front contact layer and any other layer that may be on that side of the substrate, regardless of cell orientation. Formation of the isolation scribe 26 may comprise the removal of a portion of the transparent conducting front contact layer 24.

With reference to FIG. 2C, in a third step, laser scribing, mechanical scribing, chemical etching, lithographic etching, electro-discharge machining, or any other scribing, etching, or masking methods may be used to open a substrate isolation scribe 27. This may expose a portion of the insulating carrier material layer 21. Opening the substrate isolation scribe may remove the substrate 22 in selected areas.

With reference to FIG. 2D, in a fourth step, an insulating barrier material 28 may be applied to the slope of the via scribe 25 on the side away from the isolation scribe 26 and may cover the substrate isolation scribe 27. A portion 25′ of the via scribe proximate the front contact isolation scribe 26 may be preserved or kept exposed. The barrier material could be a thermally cured or light cured material, such as a heat cured (or heat curable) polymer, a UV cured (or UV curable) polymer, or insulating tape, or any other insulating material. The barrier can be applied by screen printing, ink-jet printing, spray coating, sputtering, manual application such as hand painting using a brush, or any other method.

With reference to FIG. 2E, in a fifth step, a conducting material 36 may be applied over the barrier 28. The conducting material may extend to cover exposed via portion 25′ (of FIG. 2D) to form an electrical contact 32, and may also extend to cover a portion of the front contact (and optionally, the current collection grid 24′) of the cell away from the isolation scribe 26, forming a conductive bridge 29. The conductive material could be formed of one or more elemental metals, such as, e.g., copper, gold, silver, platinum or palladium. In an embodiment of the invention, the conductive material could be formed of a conductive ink or conductive adhesive such as silver ink, copper tape or another conductive material. Other methods, such as those disclosed previously, may be used.

With reference to FIG. 2F, in a sixth step, under illumination 33, a photo current 34 may be generated to flow (e.g., in series) between the two cells. The photovoltage of the series combination may be the sum of the photovoltages of the two cells.

It will be appreciated that more than two cells can be interconnected in series. The spacing between interconnects can be kept the same, which may allow all of the cells to generate the same amount or quantity of photocurrent. In other implementations, the spacing between interconnects may be varied, and the cells may generate varying amounts of photocurrent. With reference to FIG. 2, the metal substrate 22, semiconductor material 23, and front conducting contact 24 may be formed of any of the materials known in the art. Similarly, if the optional current collecting grid 24′ is included, it may be formed of the materials and configurations known in the art. Examples of such materials may be such as those previously disclosed in the description of FIG. 1. In some embodiments an insulating carrier material 21 may include materials such as ethyl-vinyl acetate or a fluoropolymer, or any insulating material that may provide structural support. Alternatively, materials such as silicone, silicone gel, epoxy, polydimethyl siloxane, RTV silicone rubber, polyvinyl butyral, thermoplastic polyurethane, a polycarbonate, an acrylic, a urethane, a fluoropolymer, a combination of the above materials or any other insulating material may be used. In addition, more than one layer of the above insulating materials can be used and the layers can be of different materials.

Furthermore, the concepts of U.S. Patent Application No. 2007/0079866, filed Oct. 7, 2005, which is herein incorporated by reference in its entirety, may be applied to the systems and methods for interconnection for photovoltaic modules.

It should be understood from the foregoing that, while particular implementations have been illustrated and described, various modifications can be made thereto and are contemplated herein. It is also not intended that the invention be limited by the specific examples provided within the specification. While the invention has been described with reference to the aforementioned specification, the descriptions and illustrations of the preferable embodiments herein are not meant to be construed in a limiting sense. Furthermore, it shall be understood that all aspects of the invention are not limited to the specific depictions, conFigurations or relative proportions set forth herein which depend upon a variety of conditions and variables. Various modifications in form and detail of the embodiments of the invention will be apparent to a person skilled in the art. It is therefore contemplated that the invention shall also cover any such modifications, variations and equivalents.

The above detailed description of the present invention is given for explanatory purposes. It will be apparent to those skilled in the art that numerous changes and modifications can be made without departing from the scope of the invention. Accordingly, the whole of the foregoing description is to be construed in an illustrative and not a limitative sense, the scope of the invention being defined solely by the appended claims.

I claim:

1. A method for series interconnection of solar cells, comprising steps of:
forming a complete thin-film semiconductor solar cell, comprising a semiconductor layer and a front contact layer, directly on a conducting substrate;
forming via scribes that remove the semiconductor layer and all layers above in selected areas;
forming isolation scribes that remove the front contact layer in selected areas;
applying insulating barrier materials to selected portions of the via scribes;
forming electrical interconnections that connect the top contact proximate one subcell to the back contact proximate the neighboring subcell, said connections to the back contact being formed through the via scribes;
laminating an insulating, transparent and protective encapsulant to the front of the solar cell; and
forming substrate isolation scribes to electrically connect neighboring subcells in series, said substrate isolation scribe being formed on the side of the substrate not coated with the thin-film layers.

2. The method of claim 1 wherein:
the electrical interconnections are formed by applying one or more of conductive ink, conductive adhesive or copper tape.

3. The method of claim 2 wherein:
any of the three scribing steps are laser scribing, mechanical scribing, chemical etching or electro-discharge machining.

4. The method of claim 3 wherein at least one of the scribes is performed using laser scribing.

5. The method of claim 3 wherein the transparent, protective encapsulant is ethyl-vinyl acetate.

6. The method of claim 3 wherein the insulating material is thermally cured or light-cured material.

7. The method of claim 6 wherein the insulating material is applied by one of screen printing, ink-jet printing or manual application.

8. The method of claim 3 wherein the semiconductor layers are thin-film silicon.

9. The method of claim 3 wherein the substrate is stainless steel coated with a back-reflector.

10. The method of claim 9 wherein the back-reflector is omitted.

11. The method of claim 3, wherein the scribes are performed so that at least two subcells are electrically connected so that the voltages from these subcells are added.

12. A method for series interconnection of solar cells, comprising steps of:
forming a complete thin-film semiconductor solar cell, comprising a semiconductor layer and a front contact layer, directly on a conducting substrate;
laminating an insulating backing material to the back of the solar cell;
forming via scribes that remove the semiconductor layer and all layers above in selected areas;
forming isolation scribes that remove the front contact layer in selected areas;
completely scribing the substrate within selected portions of the via scribes to form substrate isolation scribes;
applying insulating barrier materials to selected portions of the via scribes and to all portions of the substrate isolation scribes; and
forming electrical interconnections that connect the top contact proximate one subcell to the back contact proximate the neighboring subcell, said connections to the back contact being formed through the via scribes.

13. The method of claim 12 wherein the electrical interconnections are formed by applying one or more of conductive ink, conductive adhesive or copper tape.

14. The method of claim 13 wherein any of the three scribing steps are laser scribing, mechanical scribing, chemical etching or electro-discharge machining.

15. The method of claim 14 wherein at least one of the scribes is performed using laser scribing.

16. The method of claim 14 wherein the insulating backing material is comprises ethyl-vinyl acetate and a fluoropolymer.

17. The method of claim 14 wherein the insulating barrier material is thermally cured or light-cured material.

18. The method of claim 17 wherein the insulating barrier material is applied by one of screen printing, ink-jet printing or manual application.

19. The method of claim 14 wherein the semiconductor layers are thin-film silicon.

20. The method of claim 14 wherein the substrate is stainless steel coated with a back-reflector.

21. The method of claim 20 wherein the back-reflector is omitted.

22. The method of claim 14, wherein the scribes are performed so that at least two subcells are electrically connected so that the voltages from these subcells are added.
